(19) United States
(12) Patent Application Publication
(10) Pub. No.: US 2026/0302937 A1
(43) Pub. Date: Oct. 1, 2026

(54) SEMICONDUCTOR DEVICE

(71) Applicant: Renesas Electronics Corporation, Tokyo (JP)

(72) Inventors: Atsushi TSUDA, Tokyo (JP); Kosuke YAYAMA, Tokyo (JP)

(21) Appl. No.: 19/543,467

(22) Filed: Feb. 18, 2026

(30) Foreign Application Priority Data
Mar. 31, 2025 (JP) 2025-060052

(51) Int. Cl. H02M 3/07; H02M 3/158; H03K 3/03

(52) U.S. Cl. CPC H02M 3/07; H02M 3/158; H03K 3/0315

(57) ABSTRACT

The semiconductor device includes a plurality of stages of switched-capacitor circuits, in which respective switch control circuits are cascade-connected. The clock generation circuit generates a clock signal, and outputs the clock signal to a first-stage switched-capacitor circuit. Each of the switch control circuits SWCT generates switching signals for switches by processing an input clock signal from a preceding stage with logic gates, and outputs, to a succeeding stage, an output clock signal in which a delay is added to the input clock signal by the logic gates.

### CROSS-REFERENCE TO RELATED APPLICATIONS

The disclosure of Japanese Patent Application No. 2025-060052 filed on Mar. 31, 2025 including the specification, drawings and abstract is incorporated herein by reference in its entirety.

### BACKGROUND

The present invention relates to a semiconductor device, and for example, to a semiconductor device having a power regulator.

There are disclosed techniques listed below.
[Non-Patent Document 1] ESAT-MICAS, Tom Van Breussegem, “A 82% Efficiency 0.5% Ripple 16-Phase Fully Integrated Capacitive Voltage Doubler”, 2009, Symposium on VLSI Circuits Digest of Technical Papers
[Non-Patent Document 2] Yan Lu, “A Multiphase Switched-Capacitor DC-DC Converter Ring With Fast Transient Response and Small Ripple”, JOURNAL OF SOLID-STATE CIRCUITS,2017

Non-Patent Documents 1 and 2 disclose a multiphase switched-capacitor regulator. The regulator generates power by operating a plurality of switched-capacitor circuits with clock signals of multiple phases, respectively. In Non-Patent Document 1, the clock signals of multiple phases are generated by sequentially frequency-dividing a single clock signal using a plurality of frequency divider circuits connected in a tree structure. In contrast, in Non-Patent Document 2, the clock signals of multiple phases are generated by a plurality of VCO cells connected in a ring. The plurality of VCO cells is evenly distributed along the periphery of a chip.

### SUMMARY

For example, a switched-capacitor regulator is known as a power regulator for low-power applications with high power efficiency. A switched-capacitor regulator does not require an expensive inductor element that is provided in a general switching regulator. In addition, since a switched-capacitor regulator performs digital operation, the switched-capacitor regulator is suitable for scaling of a Complementary Metal Oxide Semiconductor (CMOS) process. Therefore, in particular, it is beneficial to achieve size reduction or cost reduction by implementing a switched-capacitor regulator on-chip.

On the other hand, an output power supply voltage from a switched-capacitor regulator inherently includes a ripple voltage. In particular, when the size of an output capacitor, that is, a decoupling capacitor, is limited, excessive ripple voltage may occur. Such excessive ripple voltage degrades performance of a circuit to which power is supplied and that is sensitive to noise, and in some cases causes malfunction. Therefore, in a switched-capacitor regulator, it is required to suppress the ripple voltage as much as possible.

Accordingly, for example, it may be considered to use a scheme as illustrated in Non-Patent Document 1 or Non-Patent Document 2. However, in these schemes, there is a possibility that power consumption or area overhead increases in a clock generation circuit that generates clock signals of multiple phases.

Embodiments to be described later have been made in view of such circumstances, and other problems and novel features will become apparent from the description of the present specification and the accompanying drawings.

A semiconductor device according to one embodiment includes a power supply line, a plurality of stages of switched-capacitor circuits, and a clock generation circuit. The power supply line supplies power to a predetermined load. Each of the plurality of stages of switched-capacitor circuits includes a switch, a switch control circuit, and a flying capacitor. And the respective switch control circuits are cascade-connected in the plurality of stages of switched-capacitor circuits. The clock generation circuit generates a clock signal, and outputs the clock signal to a first-stage switched-capacitor circuit among the plurality of stages of switched-capacitor circuits. Here, each of the switch control circuits generates switching signals for the switch by processing an input clock signal from a preceding stage with logic gates, and outputs, to a succeeding stage, an output clock signal in which a delay is added to the input clock signal by the logic gates. Each of the plurality of stages of switched-capacitor circuits supplies power to the common power supply line by alternately switching between a charging operation and a discharging operation with respect to the flying capacitor by switching of the switch.

According to the one embodiment, ripple voltage can be suppressed while suppressing an increase in power consumption or area overhead.

### BRIEF DESCRIPTION OF THE DRAWINGS

FIG. 1 is a circuit block diagram illustrating a schematic configuration example of a semiconductor device according to a first embodiment.

FIG. 2 is a circuit diagram illustrating a configuration example of an LDO regulator in FIG. 1.

FIG. 3A is a circuit diagram illustrating a configuration example of a switched-capacitor circuit in FIG. 1.

FIG. 3B is a timing chart illustrating a schematic operation example of a switch control circuit in FIG. 3A.

FIG. 4A is a schematic diagram for explaining a more detailed operation example of the switched-capacitor circuit illustrated in FIG. 3A.

FIG. 4B is a schematic diagram for explaining a more detailed operation example of the switched-capacitor circuit illustrated in FIG. 3A.

FIG. 5 is a circuit block diagram illustrating a configuration example of a main part of the switched-capacitor regulator illustrated in FIG. 1 in the semiconductor device according to the first embodiment.

FIG. 6A is a circuit diagram illustrating a configuration example of a switched-capacitor circuit in FIG. 5.

FIG. 6B is a timing chart illustrating an operation example of a switch control circuit in FIG. 6A.

FIG. 7A is a circuit block diagram illustrating a more detailed configuration example of the switched-capacitor regulator illustrated in FIG. 5.

FIG. 7B is a circuit diagram illustrating a configuration example of a ring oscillator circuit ROSC in FIG. 7A.

FIG. 8A is a schematic diagram illustrating a layout example of the switched-capacitor regulator illustrated in FIG. 7A within a semiconductor device.

FIG. 8B is a schematic diagram illustrating a more detailed layout example of the switched-capacitor regulator illustrated in FIG. 8A.

FIG. 8C is a schematic diagram illustrating a layout example different from that illustrated in FIG. 8B.

FIG. 9 is a schematic diagram illustrating a partial configuration example and an operation example of a switched-capacitor regulator serving as a premise in a semiconductor device according to a second embodiment.

FIG. 10 is a timing chart illustrating an example of a first problem in FIG. 9.

FIG. 11 is a timing chart illustrating an example of a second problem in FIG. 9.

FIG. 12A is a circuit diagram illustrating a configuration example of a switch control circuit illustrated in FIG. 5 in a semiconductor device according to the second embodiment.

FIG. 12B is a timing chart illustrating an operation example of the switch control circuit in FIG. 12A.

FIG. 13 is a schematic diagram illustrating a partial configuration example and an operation example of a switched-capacitor regulator including the switch control circuit illustrated in FIG. 12A.

FIG. 14 is a timing chart illustrating states of clock signals in N-stage switched-capacitor circuits illustrated in FIG. 13.

FIG. 15 is a timing chart illustrating states of an input power supply current in the N-stage switched-capacitor circuits illustrated in FIG. 13.

FIG. 16 is a circuit block diagram illustrating a detailed configuration example of a switched-capacitor regulator in a semiconductor device according to a third embodiment.

FIG. 17A is a circuit block diagram illustrating a configuration example of a main part of a general single-phase switched-capacitor regulator.

FIG. 17B is a schematic diagram illustrating an operation example of the switched-capacitor regulator illustrated in FIG. 17A.

FIG. 18A is a circuit block diagram illustrating a configuration example of a main part of a general multiphase switched-capacitor regulator.

FIG. 18B is a schematic diagram illustrating an operation example of the switched-capacitor regulator illustrated in FIG. 18A.

FIG. 19 is a circuit block diagram illustrating a configuration example of a main part of a multiphase switched-capacitor regulator as a comparative example.

### DETAILED DESCRIPTION

In the following embodiment, for convenience, descriptions will be divided into a plurality of sections or embodiments when necessary. However, unless otherwise explicitly stated, they are not unrelated to each other, and one has a relationship such as a modification, detail, or supplementary description of a part or all of the other. Further, when referring to the number of elements (including the number, numerical values, amounts, ranges, and the like), unless otherwise explicitly stated or unless it is apparent in principle that the number is limited to a specific number, the number is not limited to that specific number. That is, the number of elements may be greater or less than the specific number.

In addition, in the embodiments, constituent elements (including element steps) are not necessarily essential unless otherwise explicitly stated or unless they are considered to be clearly essential in principle. Similarly, when referring to shapes, positional relationships, and the like of constituent elements, unless otherwise explicitly stated or unless they are considered to be clearly not applicable in principle, such references include those that are substantially approximate or similar to the shapes, and the like. The same applies to the above-mentioned numerical values and ranges.

In the embodiments, a Metal Oxide Semiconductor Field Effect Transistor (MOSFET) is referred to as a MOS transistor. A p-channel MOSFET and an n-channel MOSFET are referred to as a pMOS transistor and an nMOS transistor, respectively. In the embodiments, for simplification of description, explanation is given using MOS transistors each having an oxide film as a gate insulating film. However, the gate insulating film is not necessarily limited to an oxide film.

Hereinafter, embodiments of the present invention will be described in detail with reference to the drawings. In all the drawings for explaining the embodiments, the same reference numerals are basically assigned to the same components, and repeated explanations thereof are omitted.

### First Embodiment

### <Outline of Semiconductor Device>

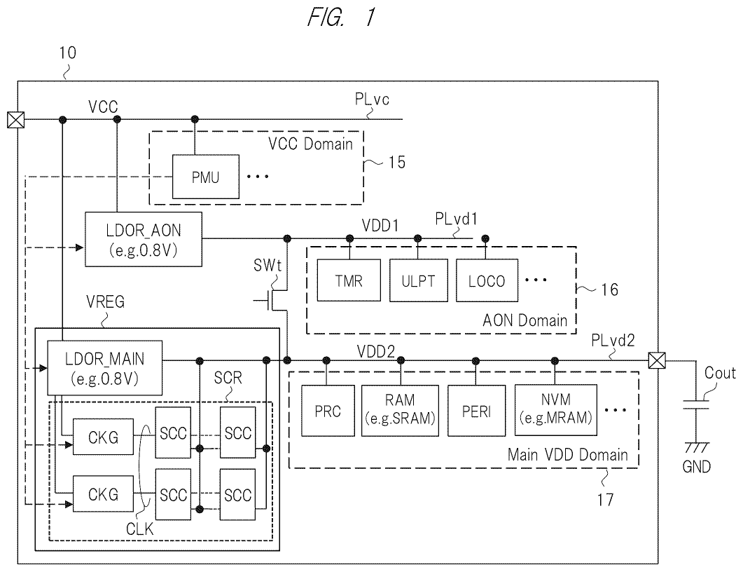

FIG. 1 is a circuit block diagram illustrating a schematic configuration example of a semiconductor device according to a first embodiment. A semiconductor device 10 illustrated in FIG. 1 is, for example, a microcontroller unit (MCU) or a system on chip (SoC) implemented by a single semiconductor chip. The semiconductor device 10 includes an LDO regulator LDOR_AON, a power regulator VREG, an external power supply circuit 15, and two internal power supply circuits 16 and 17.

The LDO regulator LDOR_AON receives an external power supply voltage VCC via a power supply line PLvc. The LDO regulator LDOR_AON generates an internal power supply voltage VDD1 lower than the external power supply voltage VCC, and outputs the internal power supply voltage VDD1 to a power supply line PLvd1. As one example, the external power supply voltage VCC is approximately 3.3 V, and the internal power supply voltage VDD1 is approximately 0.8 V. Note that the external power supply voltage VCC may vary as appropriate, for example, in the case of a battery voltage.

The power regulator VREG also receives the external power supply voltage VCC via the power supply line PLvc. The power regulator VREG generates an internal power supply voltage VDD2 lower than the external power supply voltage VCC, and outputs the internal power supply voltage VDD2 to a power supply line PLvd2. As one example the internal power supply voltage VDD2 is also approximately 0.8 V. The power regulator VREG includes an LDO regulator LDOR_MAIN and a switched-capacitor regulator SCR. In this specification, the LDO regulators LDOR_AON and LDOR_MAIN are collectively referred to as an LDO regulator LDOR.

Each of the LDO regulator LDOR_MAIN and the switched-capacitor regulator SCR operates with the external power supply voltage VCC and supplies power to a common power supply line PLvd2. The switched-capacitor regulator SCR includes a clock generation circuit CKG and a plurality of stages of switched-capacitor circuits SCC. The clock generation circuit CKG generates a clock signal CLK and supplies the clock signal CLK to the switched-capacitor circuits SCC. Details of the switched-capacitor regulator SCR will be described later.

The external power supply circuit 15 is a circuit that operates with the external power supply voltage VCC supplied via the power supply line PLvc. The external power supply circuit 15 includes, for example, a power management unit PMU. The power management unit PMU controls active and inactive states of the LDO regulator LDOR_AON and the power regulator VREG.

The internal power supply circuit 16 is a circuit that operates with the internal power supply voltage VDD1 supplied from the LDO regulator LDOR_AON via the power supply line PLvd1. The power management unit PMU controls the LDO regulator LDOR_AON to be in an active state, for example, even when the semiconductor device 10 transitions to a low-power mode. Accordingly, the internal power supply circuit 16 is a circuit that is always in an on state (AON state). The internal power supply circuit 16 includes, for example, a timer TMR, an ultra-low-power timer ULPT, and a low-frequency clock generator LOCO.

The internal power supply circuit 17 is a circuit that operates with the internal power supply voltage VDD2 supplied from the power regulator VREG via the power supply line PLvd2. The power management unit PMU controls the power regulator VREG to be in an inactive state, for example, when the semiconductor device 10 transitions to a low-power mode. In addition, the power management unit PMU controls the power regulator VREG to be in an active state when the semiconductor device 10 operates in a normal mode. Accordingly, the internal power supply circuit 17 serves as a main circuit responsible for normal operation of the semiconductor device 10.

The internal power supply circuit 17 includes, for example, a processor PRC, a volatile memory RAM, a nonvolatile memory NVM, and various peripheral circuits PERI. The processor PRC is typically a Central Processing Unit (CPU). The volatile memory RAM is, for example, a Static Random Access Memory (SRAM). The nonvolatile memory NVM is, for example, a Magnetoresistive RAM (MRAM). In this case, the processor PRC executes a predetermined program stored in the MRAM while using the SRAM as a temporary memory.

In addition, a test switch SWt illustrated in FIG. 1 is controlled to be in an on state during testing, thereby connecting two power supply lines PLvd1 and PLvd2. Accordingly, during testing, for example, a test power supply from a test terminal can be commonly supplied to the two power supply lines PLvd1 and PLvd2. In addition, in FIG. 1, the power supply line PLvd2 is connected to an output capacitor Cout provided outside the semiconductor device 10. However, the output capacitor Cout may be provided inside the semiconductor device 10.

As described above, in the semiconductor device 10, in order to reduce power consumption, a plurality of independent power domains, here the external power supply circuit 15 and the two internal power supply circuits 16 and 17, may be provided. In this case, power management for each power domain is performed using a regulator for each power domain. In particular, when a plurality of power domains is provided under a constraint on the number of external terminals of the semiconductor device 10, it is beneficial to employ a configuration in which the regulators implemented on-chip, as illustrated in FIG. 1, are integrally managed by the power management unit PMU.

### <Configuration Elements of Power Regulator>

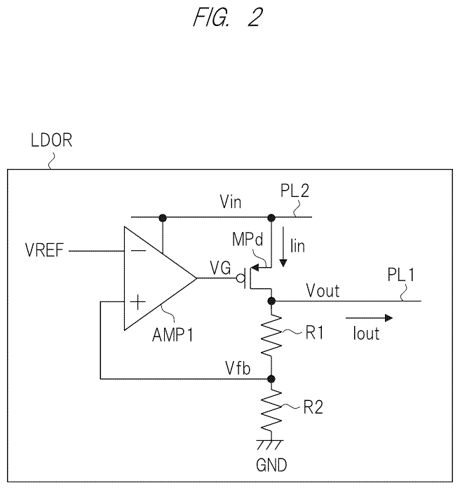

FIG. 2 is a circuit diagram illustrating a configuration example of the LDO regulator LDOR in FIG. 1. The LDO regulator LDOR illustrated in FIG. 2 includes a pMOS transistor MPd, resistive elements R1 and R2, and an amplifier circuit AMP1. The pMOS transistor MPd is connected between a power supply line PL2 to which an input power supply voltage Vin is applied and a power supply line PL1 to which an output power supply voltage Vout is output. The output power supply voltage Vout is a voltage obtained by stepping down the input power supply voltage Vin via the pMOS transistor MPd.

The amplifier circuit AMP1 applies a gate voltage VG to the pMOS transistor MPd so that an error between the value of the output power supply voltage Vout and a target value approaches zero. Specifically, the amplifier circuit AMP1 generates the gate voltage VG so that a feedback voltage Vfb matches a reference voltage VREF corresponding to the target value. The feedback voltage Vfb is generated by resistive division between the output power supply voltage Vout and a ground power supply voltage GND using two resistive elements R1 and R2 that are high-resistance elements.

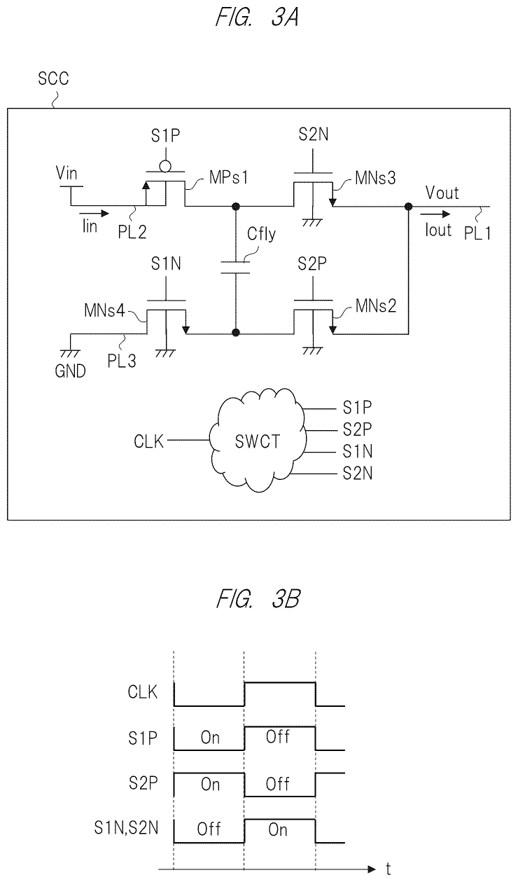

FIG. 3A is a circuit diagram illustrating a configuration example of the switched-capacitor circuit SCC in FIG. 1. FIG. 3B is a timing chart illustrating a schematic operation example of a switch control circuit SWCT in FIG. 3A. FIG. 3A illustrates, for example, a switched-capacitor circuit SCC in a case where “Voltage conversion ratio (VCR)=1/2”. The switched-capacitor circuit SCC includes four switches, one flying capacitor Cfly, and a switch control circuit SWCT.

The four switches are composed of, for example, one pMOS transistor MPs1 and three nMOS transistors MNs2 to MNs4. The pMOS transistor MPs1 and the nMOS transistor MNs3 are connected in series between a power supply line PL2 to which an input power supply voltage Vin is applied and a power supply line PL1 to which an output power supply voltage Vout is output. The two nMOS transistors MNs2 and MNs4 are connected in series between the power supply line PL1 and a power supply line PL3 to which a ground power supply voltage GND is applied.

The flying capacitor Cfly is connected between a common node of the pMOS transistor MPs1 and the nMOS transistor MNs3 and a common node of the two nMOS transistors MNs2 and MNs4. The switch control circuit SWCT generates switching signals S1P, S2P, S1N, and S2N for the four switches in synchronization with an input clock signal CLK.

The switching signal S1P controls on/off states of the pMOS transistor MPs1. The switching signal S2P controls on/off states of the nMOS transistor MNs2. The switching signal S1N controls on/off states of the nMOS transistor MNs4. The switching signal S2N controls on/off states of the nMOS transistor MNs3.

As illustrated in FIG. 3B, during an “L” level period of the clock signal CLK, the switch control circuit SWCT controls the two switching signals S1P and S2P to an on level and controls the two switching signals S1N and S2N to an off level. In this case, the input power supply voltage Vin and the output power supply voltage Vout are applied to both ends of the flying capacitor Cfly. As a result, the flying capacitor Cfly performs a charging operation based on an input power supply current Iin flowing through the power supply line PL2.

On the other hand, during an “H” level period of the clock signal CLK, the switch control circuit SWCT controls the two switching signals S1N and S2N to an on level and controls the two switching signals S1P and S2P to an off level. In this case, a ground power supply voltage GND and the output power supply voltage Vout are applied to both ends of the flying capacitor Cfly. As a result, the flying capacitor Cfly performs a discharging operation by causing an output power supply current Iout to flow through the power supply line PL1.

As described above, the switched-capacitor circuit SCC receives the input power supply voltage Vin and alternately switches between a charging operation and a discharging operation for the flying capacitor Cfly by switching in accordance with the clock signal CLK. As a result, the switched-capacitor circuit SCC supplies, to the power supply line PL1, power including the output power supply voltage Vout and the output power supply current Iout.

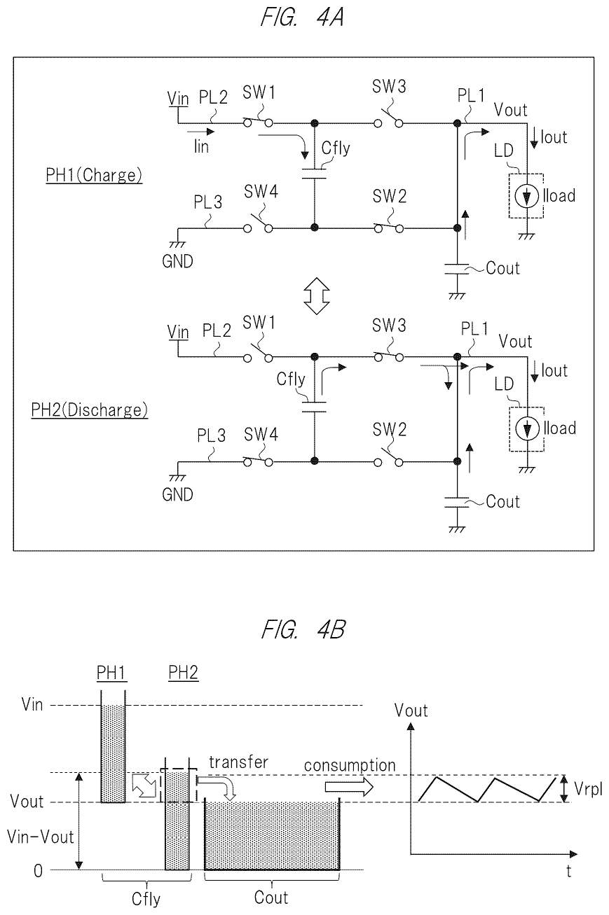

FIGS. 4A and 4B are schematic diagrams for explaining a more detailed operation example of the switched-capacitor circuit SCC illustrated in FIG. 3A. FIG. 4A illustrates on/off states of four switches SW1 to SW4 in a charging phase PH1 and a discharging phase PH2, that is, the charging operation and the discharging operation described with reference to FIG. 3A. In addition, an output capacitor Cout and a load LD are connected to the power supply line PL1 from which the output power supply voltage Vout and the output power supply current Iout are output. The load LD is represented by a current source that causes a load current Iload to flow.

In the charging phase PH1, charging of the flying capacitor Cfly is performed in a state in which the flying capacitor Cfly and the output capacitor Cout are connected in series. At this time, the input power supply voltage Vin is applied to the flying capacitor Cfly with reference to the output power supply voltage Vout. Accordingly, an input power supply current Iin flows through the power supply line PL2. On the other hand, in the discharging phase PH2, discharging from the flying capacitor Cfly to the output capacitor Cout is performed in a state in which the flying capacitor Cfly and the output capacitor Cout are connected in parallel.

Here, focusing on a transferred charge amount in the flying capacitor Cfly, an average value of the input power supply current Iin, “Iin(ave)”, is obtained by Expression (1). As illustrated in FIG. 4B, in the charging phase PH1, charging of the flying capacitor Cfly is performed with a charge amount based on “Vin−Vout”. Thereafter, in the discharging phase PH2, a charge amount based on a voltage difference “Vin−2Vout”, which is a difference between “Vin−Vout” and “Vout”, is transferred to the output capacitor Cout. The average value “Iin(ave)” of the input power supply current Iin is determined based on this transferred charge amount. In Expression (1), “f” denotes a frequency of the clock signal CLK.

Iin(ave)=Cfly(Vin−2Vout)×f (1)

In addition, in a case of “VCR=1/2,” that is, “Vout=Vin/2”, “Iout=2×Iin”. Therefore, an average value of the output power supply current Iout, “Iout(ave)”, is obtained by Expression (2). As understood from Expression (2) and FIG. 4B, when “Vin≤2Vout”, the switched-capacitor circuit SCC loses current supply capability.

Iout(ave)=2Cfly(Vin−2Vout)×f (2)

On the other hand, as illustrated in FIG. 4B, the output power supply voltage Vout from the switched-capacitor circuit SCC inherently includes a ripple voltage Vrpl due to repetition of the charging operation and the discharging operation. Here, in a steady state of the load LD, a relationship of “Iout(ave)=Iload” holds. Therefore, the ripple voltage Vrpl is obtained by Expression (3), where a transferred charge amount per unit time “dt” is “dQ.” As understood from Expression (3), in order to suppress the ripple voltage Vrpl, it is necessary to reduce the load current Iload, increase the output capacitor Cout, or increase a frequency “f” of the clock signal CLK.

Vrpl=dQ/Cout=(Iout(ave)×dt)/Cout=Iload/(Cout×f) (3)

### <Various Methods of Suppressing Ripple Voltage>

When the ripple voltage Vrpl illustrated in FIG. 4B becomes large, malfunction may occur in the load LD, for example, the internal power supply circuit 17 illustrated in FIG. 1. Therefore, it is required to suppress the ripple voltage Vrpl. Here, in a case where a single switched-capacitor circuit SCC is used, a method of increasing the output capacitor Cout can be considered as a method of suppressing the ripple voltage Vrpl. However, increasing the size of the output capacitor Cout is not preferable because it leads to an increase in size and cost of a system including the semiconductor device 10. Furthermore, when the output capacitor Cout is implemented on-chip, forming a large output capacitor Cout itself may be difficult.

In addition, as another method, a method of increasing a frequency “f” of the clock signal CLK, that is, a switching frequency “f”, can be considered. However, in this case, since switching loss increases, it becomes difficult to obtain high power efficiency, which is an advantage of the switched-capacitor circuit SCC. Furthermore, in various control circuits responsible for control of the switched-capacitor circuit SCC, power consumption also increases, and timing design may become complicated. Therefore, it is desirable that the switching frequency “f” be lower.

Furthermore, as another method, a method of variably controlling a capacitance value of the flying capacitor Cfly or a method of variably controlling on-resistances of the four switches SW1 to SW4 illustrated in FIG. 4A can also be considered. However, when these methods are used, a circuit configuration and control become complicated, and design difficulty also increases. Accordingly, a method using a multiphase switched-capacitor regulator as illustrated in Non-Patent Document 1 or Non-Patent Document 2 can be considered.

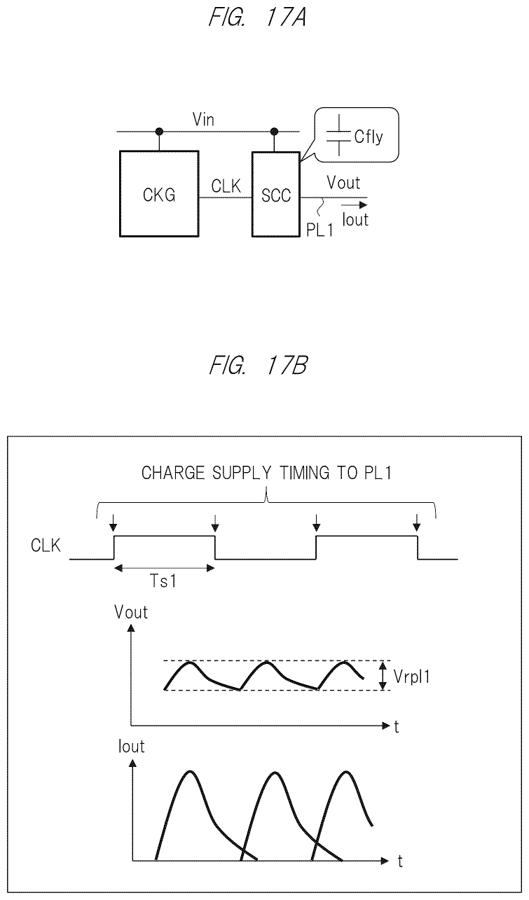

FIG. 17A is a circuit block diagram illustrating a configuration example of a main part of a general single-phase switched-capacitor regulator. FIG. 17B is a schematic diagram illustrating an operation example of the switched-capacitor regulator illustrated in FIG. 17A. In FIG. 17A, one switched-capacitor circuit SCC is provided. The switched-capacitor circuit SCC performs a switching operation in synchronization with a clock signal CLK from a clock generation circuit CKG.

More specifically, as illustrated in FIG. 17B, the switched-capacitor circuit SCC can supply charge to the power supply line PL1 at rising edges and falling edges of the clock signal CLK. Therefore, an interval Ts1 of charge supply timing is equal to an edge interval of the clock signal CLK. Further, a ripple voltage Vrpl1 increases as a charge amount supplied per time, and thus a capacitance value of the flying capacitor Cfly, increases. In addition, the ripple voltage Vrpl increases as the interval Ts1 of charge supply becomes longer.

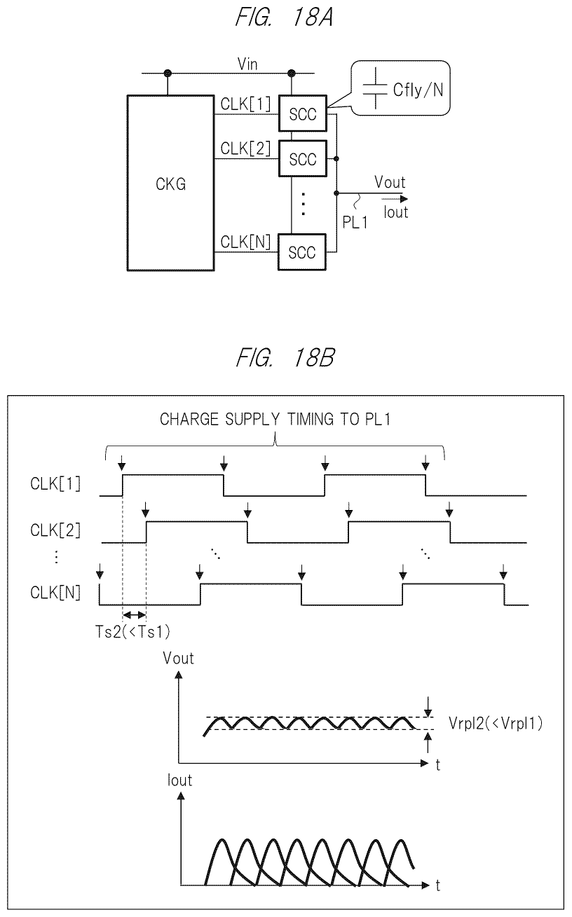

FIG. 18A is a circuit block diagram illustrating a configuration example of a main part of a general multiphase switched-capacitor regulator. FIG. 18B is a schematic diagram illustrating an operation example of the switched-capacitor regulator illustrated in FIG. 18A. In FIG. 18A, unlike the case of FIG. 17A, N switched-capacitor circuits SCC are provided. The N switched-capacitor circuits SCC each supply power to a common power supply line PL1.

Here, each of the N switched-capacitor circuits SCC includes a flying capacitor Cfly having a capacitance value of 1/N as compared with the case of FIG. 17A. However, when the N switched-capacitor circuits SCC are viewed as a whole, a capacitance value of the flying capacitors Cfly is the same as in the case of FIG. 17A. As illustrated in FIG. 18B, the clock generation circuit CKG generates N-phase clock signals CLK[1] to CLK[N] having phases different from each other. The N switched-capacitor circuits SCC perform switching operations in synchronization with the N-phase clock signals CLK[1] to CLK[N], respectively.

When such a multiphase type is used, an interval Ts2 of charge supply timing is equal to an edge interval between two adjacent clock signals CLK. Therefore, the interval Ts2 becomes shorter than the interval Ts1 illustrated in FIG. 17B. Furthermore, a capacitance value of the flying capacitor Cfly is 1/N of that in the case of FIG. 17A. Accordingly, a charge amount supplied per time is also smaller than that in the case of FIG. 17A. As a result, a ripple voltage Vrpl2 can be significantly suppressed as compared with the case of FIG. 17B.

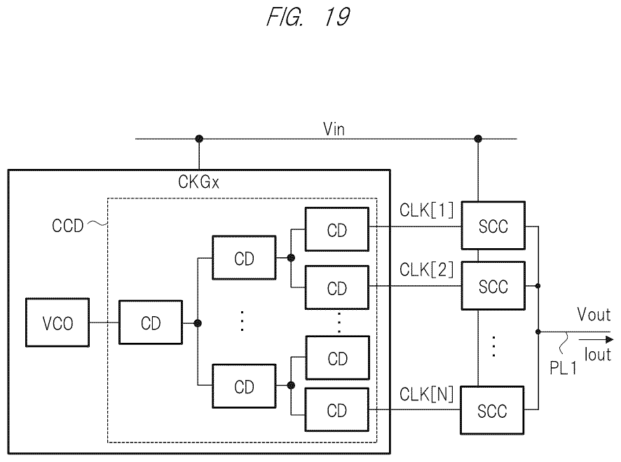

FIG. 19 is a circuit block diagram illustrating a configuration example of a main part of a multiphase switched-capacitor regulator as a comparative example. FIG. 19 illustrates a detailed configuration example of the clock generation circuit CKG illustrated in FIG. 18A. A clock generation circuit CKGx illustrated in FIG. 19 includes a voltage-controlled oscillator VCO and a cascade-type clock frequency divider circuit CCD provided at a subsequent stage. The cascade-type clock frequency divider circuit CCD is composed of a plurality of clock frequency divider circuits CD connected in a tree structure. Each clock frequency divider circuit CD frequency-divides a clock signal input from a preceding stage while shifting a phase.

However, when such a configuration is used, it is necessary to set a clock signal from the voltage-controlled oscillator VCO to a high frequency. Furthermore, by providing the cascade-type clock frequency divider circuit CCD, a circuit scale also becomes large. As a result, in the clock generation circuit CKGx, there is a possibility that power consumption or area overhead increases. Accordingly, there is a possibility that high power efficiency, which is an advantage of the switched-capacitor circuit SCC, cannot be sufficiently obtained. Therefore, it is beneficial to use a method described below.

### <Outline of Switched-Capacitor Regulator (Embodiment)>

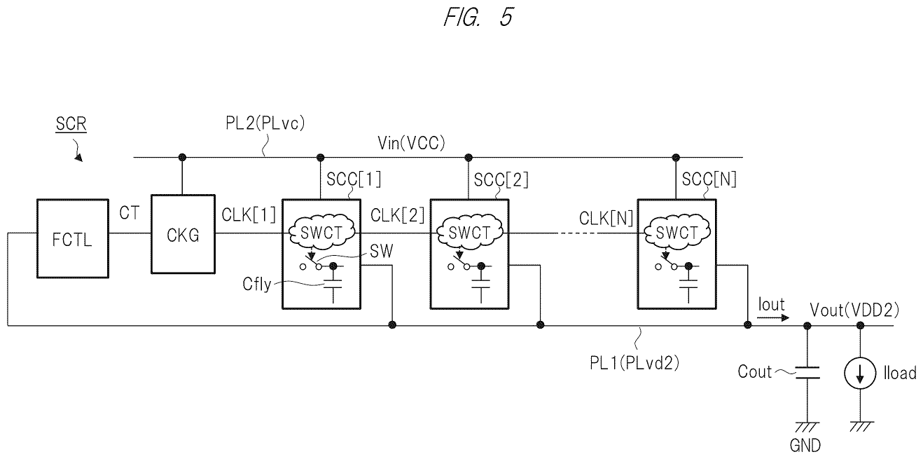

FIG. 5 is a circuit block diagram illustrating a configuration example of a main part of the switched-capacitor regulator SCR illustrated in FIG. 1 in the semiconductor device according to the first embodiment. The switched-capacitor regulator SCR illustrated in FIG. 5 operates with an input power supply voltage Vin supplied from a power supply line PL2. The switched-capacitor regulator SCR generates an output power supply voltage Vout obtained by stepping down the input power supply voltage Vin and an output power supply current Iout, and outputs the output power supply voltage Vout and the output power supply current Iout to a power supply line PL1.

Referring to FIG. 1, the power supply line PL2 and the input power supply voltage Vin correspond to the power supply line PLvc and the external power supply voltage VCC, respectively. The power supply line PL1 and the output power supply voltage Vout correspond to the power supply line PLvd2 and the internal power supply voltage VDD2, respectively. The power supply line PL1 supplies power to a predetermined load that causes a load current Iload to flow, for example, the internal power supply circuit 17.

In addition, the switched-capacitor regulator SCR includes a frequency control circuit FCTL, a clock generation circuit CKG, and a plurality of stages, that is, N stages of switched-capacitor circuits SCC[1] to SCC[N]. N is an integer equal to or greater than 2. In this specification, the switched-capacitor circuits are collectively referred to as switched-capacitor circuits SCC. Each of the N stages of switched-capacitor circuits SCC includes, as illustrated in FIGS. 3A and 4A, switches SW, a switch control circuit SWCT, and a flying capacitor Cfly. In the N stages of switched-capacitor circuits SCC, the respective switch control circuits SWCT are connected in cascade.

The frequency control circuit FCTL outputs, for example, a control signal CT so that an error between the output power supply voltage Vout and a target value approaches zero. The clock generation circuit CKG generates a clock signal CLK[1] and controls a frequency of the clock signal CLK[1] based on the control signal CT. The clock generation circuit CKG outputs the generated clock signal CLK[1] to a first-stage switched-capacitor circuit SCC[1] among the N stages of switched-capacitor circuits SCC.

In each stage of the switched-capacitor circuits SCC, a switch control circuit SWCT generates switching signals for switches SW by processing an input clock signal from a preceding stage with logic gates. Accordingly, as illustrated in FIGS. 3A and 4A, each stage of the switched-capacitor circuits SCC alternately switches between a charging operation and a discharging operation for the flying capacitor Cfly by switching of the switches SW. Each stage of the switched-capacitor circuits SCC supplies power to the common power supply line PL1 by switching between the charging operation and the discharging operation.

Furthermore, the switch control circuit SWCT outputs, to a subsequent stage, an output clock signal obtained by adding a delay to the input clock signal by logic gates. That is, in the first-stage switched-capacitor circuit SCC[1], the switch control circuit SWCT receives the clock signal CLK[1] from the clock generation circuit CKG as an input clock signal. Then, the switch control circuit SWCT outputs, as an output clock signal, a clock signal CLK[2] obtained by adding a delay to the clock signal CLK[1].

In the second-stage switched-capacitor circuit SCC[2], the switch control circuit SWCT receives the clock signal CLK[2] from the first stage as an input clock signal. Then, the switch control circuit SWCT outputs, as an output clock signal, a clock signal, not illustrated, CLK[3], obtained by adding a delay to the clock signal CLK[2]. Similarly thereafter, in the N-th-stage switched-capacitor circuit SCC[N], the switch control circuit SWCT receives a clock signal CLK[N] from the “(N−1)-th” stage of the switched-capacitor circuit.

By using such a configuration, multiphase operation as described with reference to FIGS. 18A and 18B can be implemented by utilizing delays in logic gates in the switch control circuits SWCT. As a result, ripple voltage can be suppressed while suppressing an increase in power consumption or area overhead. Specifically, for example, a cascade-type clock frequency divider circuit CCD as in the comparative example illustrated in FIG. 19 is not required. Therefore, an increase in power consumption or area overhead associated with such a circuit can be suppressed.

In addition, a frequency of the clock signal CLK[1] from the clock generation circuit CKG may be lower than in the case of FIG. 19. This also makes it possible to suppress an increase in power consumption. Furthermore, in the clock generation circuit CKG, difficulty of timing design can be reduced due to low-speed operation. Note that the switched-capacitor circuit SCC is not limited to a configuration as illustrated in FIG. 3A, and various configurations can be employed. However, in any configuration, a switch control circuit SWCT corresponding to the configuration is provided. Since the method illustrated in FIG. 5 is a method in which the switch control circuits SWCT are connected in cascade, the method does not depend on a configuration of the switched-capacitor circuits SCC, that is, the method has high versatility.

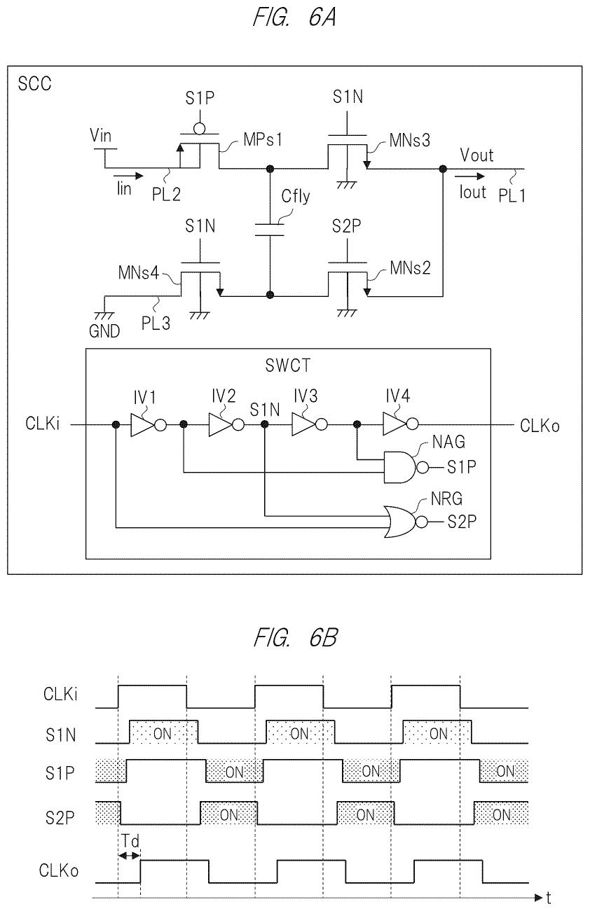

FIG. 6A is a circuit diagram illustrating a configuration example of the switched-capacitor circuit SCC in FIG. 5. FIG. 6B is a timing chart illustrating an operation example of the switch control circuit SWCT in FIG. 6A. The switched-capacitor circuit SCC illustrated in FIG. 6A includes, similarly to the case of FIG. 3A, four switches SW, a flying capacitor Cfly, and a switch control circuit SWCT. The four switches SW are composed of a pMOS transistor MPs1 and three nMOS transistors MNs2 to MNs4.

On/off states of the pMOS transistor MPs1 and the nMOS transistor MNs2 are controlled by a switching signal S1P and a switching signal S2P, respectively, similarly to the case of FIG. 3A. On the other hand, on/off states of the remaining two nMOS transistors MNs3 and MNs4 are, here, unlike the case of FIG. 3A, controlled by a common switching signal S1N. However, similarly to the case of FIG. 3A, individual switching signals S1N and S2N may also be used.

The switch control circuit SWCT includes, for example, four-stage inverter circuits IV1 to IV4 connected in cascade, a NAND gate NAG, and a NOR gate NRG. As illustrated in FIG. 6B, the four-stage inverter circuits IV1 to IV4 receive an input clock signal CLKi and output an output clock signal CLKo obtained by adding a predetermined delay time Td. In addition, an output signal from the second-stage inverter circuit IV2 is used as the switching signal S1N.

The NAND gate NAG receives an output signal from the first-stage inverter circuit IV1 and an output signal from the third-stage inverter circuit IV3 and performs a NAND operation. The NAND gate NAG outputs a result of the NAND operation as the switching signal S1P. The NOR gate NRG receives the input clock signal CLKi and the output signal from the second-stage inverter circuit IV2 and performs a NOR operation. The NOR gate NRG outputs a result of the NOR operation as the switching signal S2P.

Here, the pMOS transistor MPs1 and the nMOS transistor MNs3 need to be controlled so that overlapping on periods do not occur in order to prevent through current. Similarly, the two nMOS transistors MNs2 and MNs4 also need to be controlled so that overlapping on periods do not occur. Therefore, as illustrated in FIG. 6B, the switch control circuit SWCT provides appropriate dead times between the switching signals S1N, S1P, and S2P. For example, the switch control circuit SWCT transitions the switching signal S1N to an off level and then transitions the switching signal S1P to an on level after a predetermined dead time has elapsed.

As described above, since dead time is provided, the switch control circuit SWCT may include logic gates that add delay, here inverter circuits IV1 to IV3. In the method of the embodiment, multiphase operation is implemented by utilizing such delays caused by the logic gates. Note that the configuration of the switch control circuit SWCT is not limited to the configuration illustrated in FIG. 6A and may be appropriately modified. However, in any configuration, the switch control circuit SWCT may include logic gates that add delay.

### <Details of Switched-Capacitor Regulator>

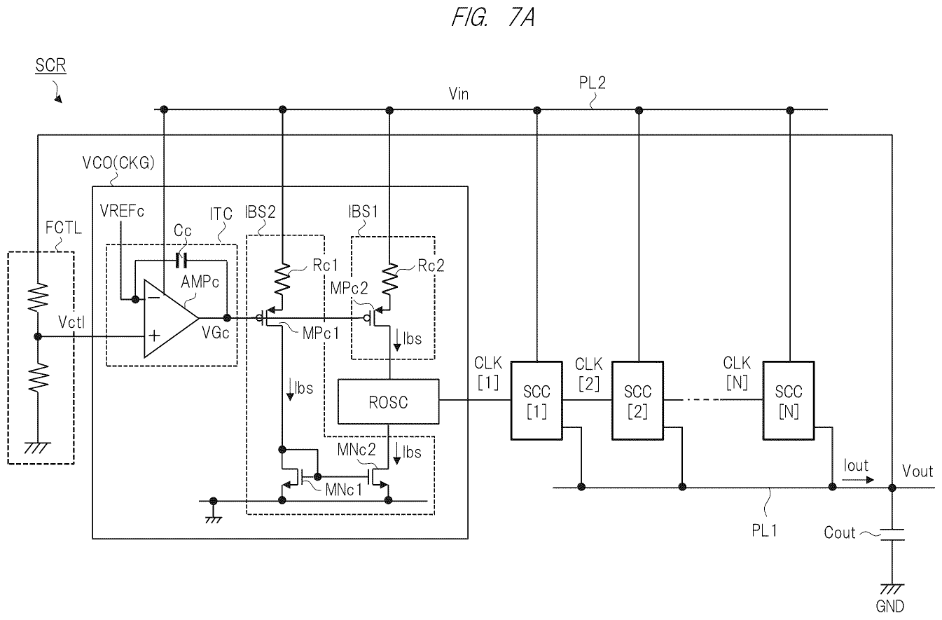

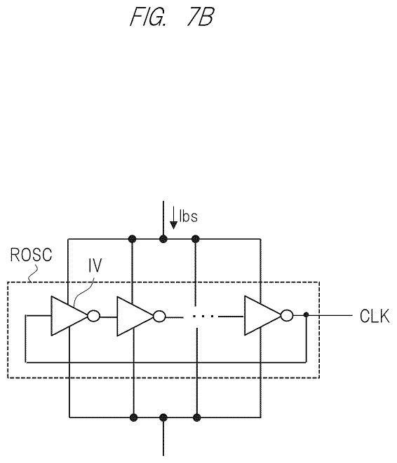

FIG. 7A is a circuit block diagram illustrating a more detailed configuration example of the switched-capacitor regulator SCR illustrated in FIG. 5. FIG. 7B is a circuit diagram illustrating a configuration example of a ring oscillator circuit ROSC in FIG. 7A. In FIG. 7A, a detailed configuration example of the frequency control circuit FCTL and the clock generation circuit CKG is illustrated with respect to the configuration illustrated in FIG. 5. The frequency control circuit FCTL generates a frequency control voltage Vctl by resistively dividing the output power supply voltage Vout. The clock generation circuit CKG is composed of, for example, a voltage-controlled oscillator VCO.

The voltage-controlled oscillator VCO includes an integration circuit ITC, a high-side bias circuit IBS1, a low-side bias circuit IBS2, and a ring oscillator circuit ROSC. As illustrated in FIG. 7B, the ring oscillator circuit ROSC includes a plurality of stages of inverter circuits IV connected in cascade and a feedback wiring between an input and an output.

The integration circuit ITC includes an amplifier circuit AMPc and an integration capacitor Cc. The amplifier circuit AMPc integrates an error between a predetermined reference voltage VREFc and the frequency control voltage Vctl using the integration capacitor Cc. The reference voltage VREFc is set to a voltage based on a target value of the output power supply voltage Vout. That is, here, the integration circuit ITC functions as a part of the frequency control circuit FCTL that detects an error between the output power supply voltage Vout and the target value.

Then, the amplifier circuit AMPc outputs a result of integration of the above-described error as a gate voltage (bias control voltage) VGc. The two bias circuits IBS1 and IBS2 generate a bias current Ibs based on the integration result. The ring oscillator ROSC operates with the bias current Ibs.

Specifically, the bias circuit IBS1 includes a pMOS transistor MPc2 and a resistive element Rc2. The pMOS transistor MPc2 supplies the bias current Ibs based on the gate voltage VGc to a high-potential-side power supply node of the ring oscillator ROSC. The resistive element Rc2 is connected between a source of the pMOS transistor MPc2 and the power supply line PL2.

The bias circuit IBS2 includes a pMOS transistor MPc1, a resistive element Rc1, and two nMOS transistors MNc1 and MNc2. The pMOS transistor MPc1 causes the bias current Ibs based on the gate voltage VGc to flow. The resistive element Rc1 is connected between a source of the pMOS transistor MPc1 and the power supply line PL2. The nMOS transistors MNc1 and MNc2 constitute a current mirror circuit. The nMOS transistor MNc1 copies the bias current Ibs flowing through the pMOS transistor MPc1 to the nMOS transistor MNc2. The nMOS transistor MNc2 supplies the copied bias current Ibs to a low-potential-side power supply node of the ring oscillator ROSC.

The inverter circuits IV in the ring oscillator ROSC perform signal inversion operations at a speed corresponding to a magnitude of the supplied bias current Ibs. Thus, the ring oscillator ROSC generates a clock signal CLK[1] having a frequency corresponding to the magnitude of the supplied bias current Ibs. Then, the ring oscillator ROSC outputs the generated clock signal CLK[1] to the first-stage switched-capacitor circuit SCC[1].

Here, when “Vctl<VREFc”, for example, the integration circuit ITC outputs a relatively low voltage as the gate voltage (bias control voltage) VGc. As a result, the two bias circuits IBS1 and IBS2 increase the bias current Ibs, and the ring oscillator ROSC increases a frequency of the clock signal CLK. On the other hand, when “Vctl>VREFc”, the integration circuit ITC outputs a relatively high voltage as the gate voltage VGc. As a result, the two bias circuits IBS1 and IBS2 decrease the bias current Ibs, and the ring oscillator ROSC decreases the frequency of the clock signal CLK.

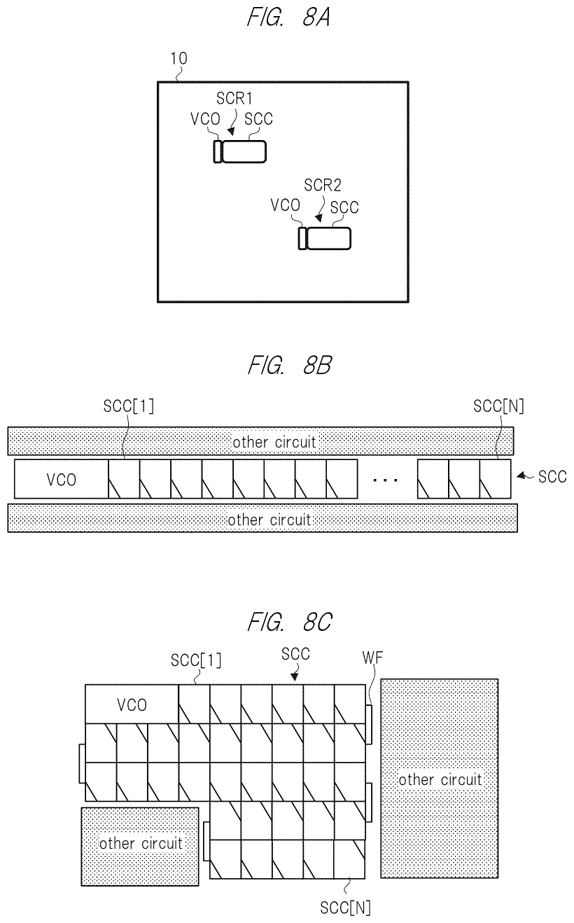

FIG. 8A is a schematic diagram illustrating a layout example of the switched-capacitor regulator SCR illustrated in FIG. 7A within the semiconductor device 10. FIG. 8B is a schematic diagram illustrating a more detailed layout example of the switched-capacitor regulator SCR illustrated in FIG. 8A. FIG. 8C is a schematic diagram illustrating a layout example different from that illustrated in FIG. 8B.

In the example illustrated in FIG. 8A, two switched-capacitor regulators SCR1 and SCR2 are arranged in a distributed manner within the semiconductor device 10. Each of the two switched-capacitor regulators SCR1 and SCR2 includes a voltage-controlled oscillator VCO and N stages of switched-capacitor circuits SCC.

As a specific example, the two switched-capacitor regulators SCR1 and SCR2 may be arranged in the vicinity of locations where loads with large current consumption are arranged. As a result, an IR drop in the entire semiconductor device 10 can be suppressed. In addition, in each switched-capacitor regulator SCR, the number of stages of the switched-capacitor circuits SCC may be appropriately adjusted according to an amount of current required by the load. More specifically, the number of stages is determined in consideration of, in addition to the amount of current, transient response characteristics of the load and stability of a control loop.

Here, the semiconductor device 10 normally includes various circuits. At this time, within the semiconductor device 10, vacant regions of various shapes may be generated due to differences in sizes or shapes of the respective circuits. The switched-capacitor regulator SCR illustrated in FIG. 7A is arranged in various shapes in accordance with such vacant regions of various shapes. In the example illustrated in FIG. 8B, a vacant region is generated such that it extends in one direction. Accordingly, the N stages of switched-capacitor circuits SCC[1] to SCC[N] are arranged in a straight line in sequence.

On the other hand, in the example illustrated in FIG. 8C, a vacant region is generated such that it has a rectangular shape with a portion cut out. Accordingly, the N stages of switched-capacitor circuits SCC are arranged in a plurality of rows while being folded back at intermediate stages from the first-stage switched-capacitor circuit SCC[1] toward the final-stage, that is, the N-th-stage switched-capacitor circuit SCC[N]. In this example, the N stages of switched-capacitor circuits SCC are arranged in five rows using folded-back wiring WF for transmitting the clock signal CLK.

Here, for example, in a general multiphase configuration illustrated in FIG. 18A, if variations occur in wiring lengths between the clock generation circuit CKG and the N switched-capacitor circuits SCC, phases of the clock signal CLK also vary. When variations in the phases become large, normal multiphase operation becomes difficult. Therefore, in arrangement of the clock generation circuit CKG and the N switched-capacitor circuits SCC, a constraint for realizing equal-length wiring is imposed.

On the other hand, in the switched-capacitor regulator SCR according to the embodiment, such a constraint of equal-length wiring does not occur. Therefore, for example, as illustrated in FIG. 8C, the switched-capacitor regulator SCR can be arranged in a relatively free shape. As a result, vacant regions within the semiconductor device 10 can be effectively utilized, and area efficiency of the semiconductor device 10 can be improved, thereby making it possible to reduce a chip size. Note that, in the method of the embodiment, a certain degree of constraint may occur on lengths of clock wirings that connect adjacent switched-capacitor circuits SCC.

### Here, Supplementary Description Will Be Given Regarding a

positional relationship between the voltage-controlled oscillator VCO and the switched-capacitor circuits SCC. A distance between the switched-capacitor circuit SCC[1] arranged closest to the voltage-controlled oscillator VCO and the voltage-controlled oscillator VCO is defined as a shortest distance. In addition, a distance between a switched-capacitor circuit arranged farthest from the voltage-controlled oscillator VCO, for example, SCC[N], and the voltage-controlled oscillator VCO is defined as a longest distance. In the method of the embodiment, since the constraint of equal-length wiring does not occur, the longest distance may be twice or more the shortest distance.

### <Main Effects of First Embodiment>

As described above, in the method of the first embodiment, a plurality of stages of switched-capacitor circuits SCC is provided so that the switch control circuits SWCT included in the respective stages are connected in cascade. Then, multiphase operation is implemented by utilizing delays of logic gates constituting the switch control circuits SWCT. As a result, ripple voltage can be suppressed while suppressing an increase in power consumption or area overhead.

### Second Embodiment

### <Underlying Problems>

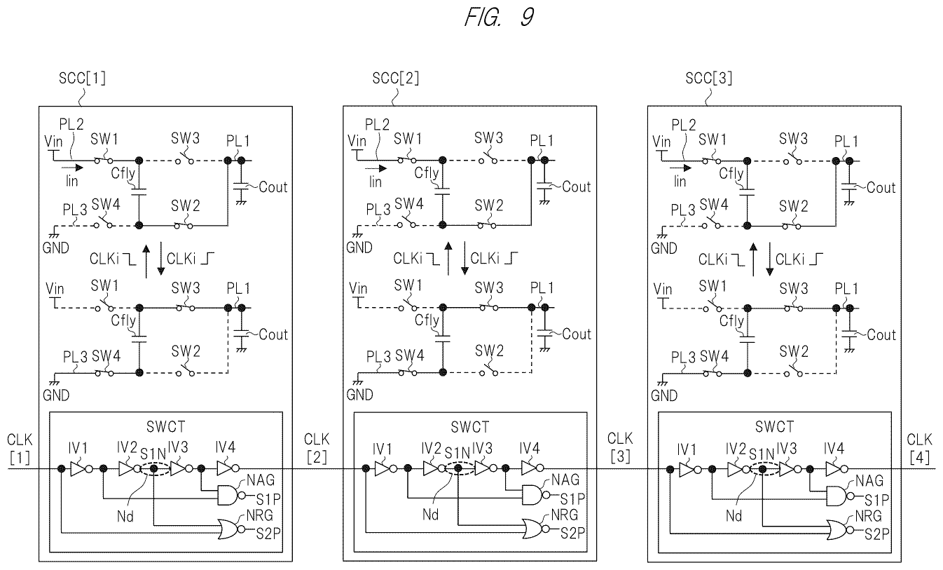

FIG. 9 is a schematic diagram illustrating a configuration example and an operation example of a part of a switched-capacitor regulator that serves as a premise in a semiconductor device according to a second embodiment. FIG. 9 illustrates configuration an example and an operation example of three stages of switched-capacitor circuits SCC[1] to SCC[3] among N stages of switched-capacitor circuits SCC connected in cascade.

As illustrated in FIG. 9, when the clock signal CLK[1] falls, the three switched-capacitor circuits SCC[1] to SCC[3] sequentially start charging operations for the flying capacitor Cfly. In addition, when the clock signal CLK[1] rises, the three switched-capacitor circuits SCC[1] to SCC[3] sequentially start discharging operations from the flying capacitor Cfly.

However, in such a configuration and operation, the following two problems may occur. As a first problem, a duty ratio of the clock signal CLK may change toward later-stage switched-capacitor circuits SCC. As a result, in some cases, loss of the clock signal CLK may occur. As a second problem, imbalance may occur in the input power supply current Iin.

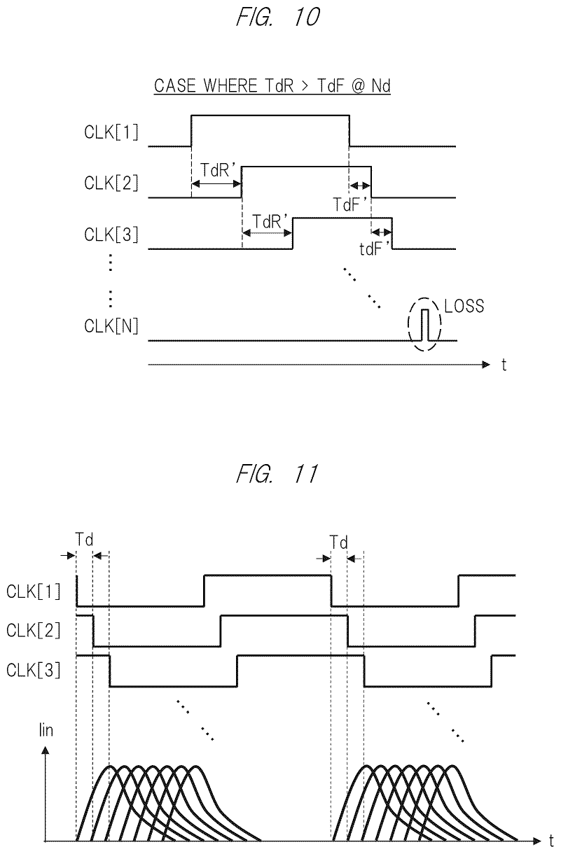

FIG. 10 is a timing chart illustrating an example of the first problem in FIG. 9. For example, a case is assumed in which, at an output node Nd of the inverter circuit IV2 in the switch control circuit SWCT, a rising delay time TdR of a signal is longer than a falling delay time TdF. In this case, as illustrated in FIG. 10, in the N clock signals CLK[1] to CLK[N], a relatively long delay time TdR′ is added at rising edges. On the other hand, a relatively short delay time TdF′ is added at falling edges. As a result, in the N clock signals CLK[1] to CLK[N], an “H” pulse width becomes narrower toward later stages, and in some cases, loss of the pulses may occur.

FIG. 11 is a timing chart illustrating an example of the second problem in FIG. 9. As described above, when the clock signal CLK[1] falls, the three switched-capacitor circuits SCC[1] to SCC[3] sequentially start charging operations for the flying capacitor Cfly. In the power supply line PL2, the input power supply current Iin flows at each delay time Td in accordance with the charging operations. As a result, as illustrated in FIG. 11, depending on a value of the number of stages “N” and the delay time Td of each stage, imbalance may occur in the input power supply current Iin. Such imbalance, for example, largely fluctuates the input power supply voltage Vin on the power supply line PL2. Accordingly, it is beneficial to use a method described below.

### <Details of Switch Control Circuit>

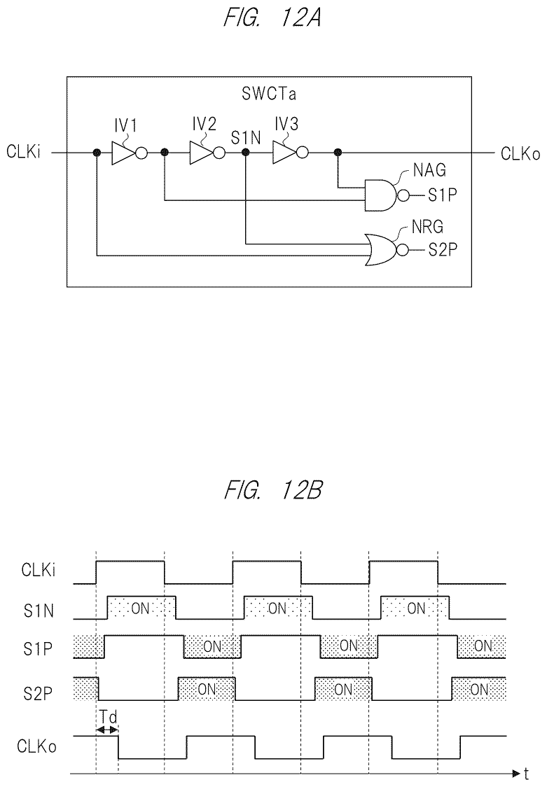

FIG. 12A is a circuit diagram illustrating a configuration example of a switch control circuit illustrated in FIG. 5 in a semiconductor device according to a second embodiment. FIG. 12B is a timing chart illustrating an operation example of the switch control circuit SWCTa in FIG. 12A. The switch control circuit SWCTa illustrated in FIG. 12A differs from the configuration example illustrated in FIG. 6A in the following point. That is, a final-stage inverter circuit IV4 is removed. As a result, as illustrated in FIG. 12B, the switch control circuit SWCTa outputs, as an output clock signal CLKo, an inverted signal of the input clock signal CLKi while adding a delay time Td to the input clock signal CLKi.

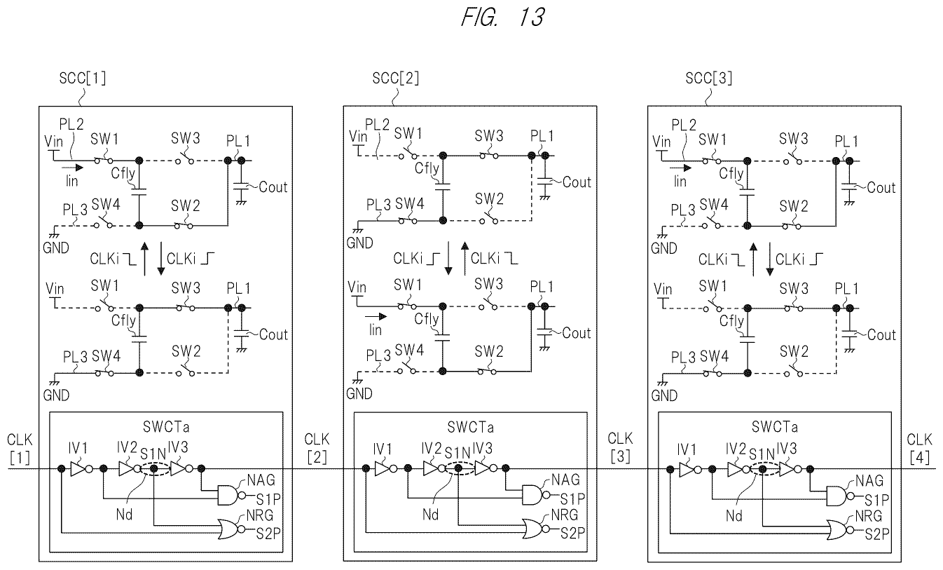

FIG. 13 is a schematic diagram illustrating a configuration example and an operation example of a part of a switched-capacitor regulator including the switch control circuit SWCTa illustrated in FIG. 12A. In FIG. 13, similarly to the case of FIG. 9, a configuration example and an operation example of three stages of switched-capacitor circuits SCC[1] to SCC[3] are illustrated. However, unlike the case of FIG. 9, each of the three switched-capacitor circuits SCC[1] to SCC[3] includes the switch control circuit SWCTa illustrated in FIG. 12A.

As illustrated in FIG. 13, when the clock signal CLK[1] falls, the odd-numbered stages of switched-capacitor circuits SCC[1], SCC[3], . . . sequentially start charging operations for the flying capacitor Cfly. On the other hand, the even-numbered stages of switched-capacitor circuits SCC[2], SCC[4], . . . sequentially start discharging operations from the flying capacitor Cfly.

In addition, when the clock signal CLK[1] rises, the odd-numbered stages of switched-capacitor circuits SCC[1], SCC[3], . . . sequentially start discharging operations from the flying capacitor Cfly. On the other hand, the even-numbered stages of switched-capacitor circuits SCC[2], SCC[4], . . . sequentially start charging operations for the flying capacitor Cfly. In this manner, the N stages of switched-capacitor circuits SCC alternate charging operations and discharging operations for each stage.

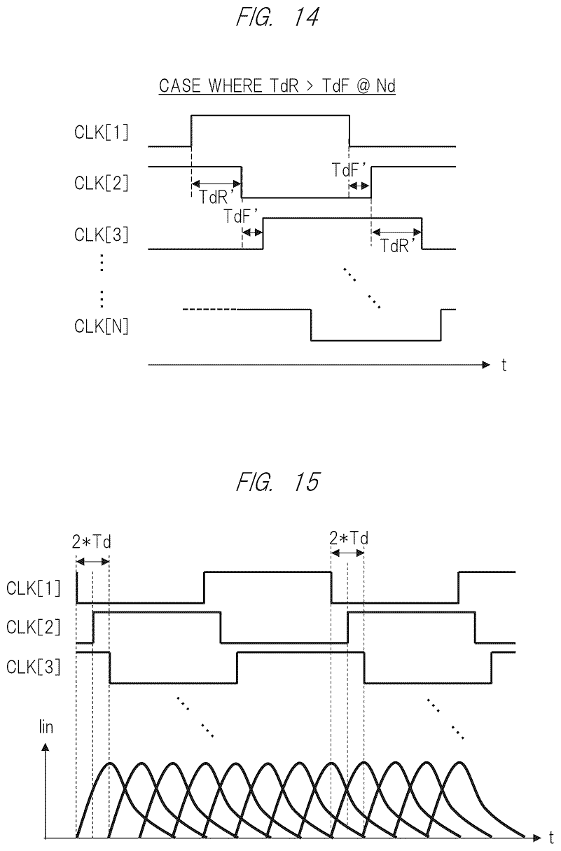

FIG. 14 is a timing chart illustrating states of clock signals in the N stages of switched-capacitor circuits SCC illustrated in FIG. 13. Here again, similarly to the case of FIG. 10, a case is assumed in which, at an output node Nd of the inverter circuit IV2 in the switch control circuit SWCTa, a rising delay time TdR of a signal is longer than a falling delay time TdF.

In this case, as illustrated in FIG. 14, the second-stage clock signal CLK[2] falls after a relatively long delay time TdR′ in response to a rising edge of the first-stage clock signal CLK[1]. In addition, the second-stage clock signal CLK[2] rises after a relatively short delay time TdF′ in response to a falling edge of the first-stage clock signal CLK[1]. Subsequently, the third-stage clock signal CLK[3] rises after a relatively short delay time TdF′ in response to a falling edge of the second-stage clock signal CLK[2]. In addition, the third-stage clock signal CLK[3] falls after a relatively long delay time TdR′ in response to a rising edge of the second-stage clock signal CLK[2].

As a result, the second-stage clock signal CLK[2] becomes a signal having an “L” pulse width obtained by narrowing an “H” pulse width of the first-stage clock signal CLK[1]. The third-stage clock signal CLK[3] becomes a signal having an “H” pulse width obtained by widening an “L” pulse width of the second-stage clock signal CLK[2]. In this manner, since an operation of narrowing a pulse width and an operation of widening a pulse width are alternately performed, unlike the case of FIG. 10, a duty ratio of the clock signal CLK can be maintained even in later stages. As a result, operation of the switched-capacitor circuits SCC in later stages can be more reliably ensured.

FIG. 15 is a timing chart illustrating a state of an input power supply current Iin in the N stages of switched-capacitor circuits SCC illustrated in FIG. 13. In FIG. 15, the input power supply current Iin flows at every double delay time Td, unlike the delay time Td in the case of FIG. 11. As a result, as illustrated in FIG. 15, imbalance of the input power supply current Iin can be reduced as compared with the case of FIG. 11. Consequently, for example, fluctuation of the input power supply voltage Vin on the power supply line PL2, that is, the external power supply voltage VCC in FIG. 1, can be suppressed.

### <Main Effects of Second Embodiment>

As described above, by using the method of the second embodiment, effects similar to the various effects described in the first embodiment can be obtained. In addition, duty ratios of the clock signals CLK of the respective phases can be maintained, and in particular, operation of the switched-capacitor circuits SCC in later stages can be more reliably ensured. Furthermore, fluctuation of the input power supply voltage Vin can be suppressed.

### Third Embodiment

### <Details of Power Supply Regulator>

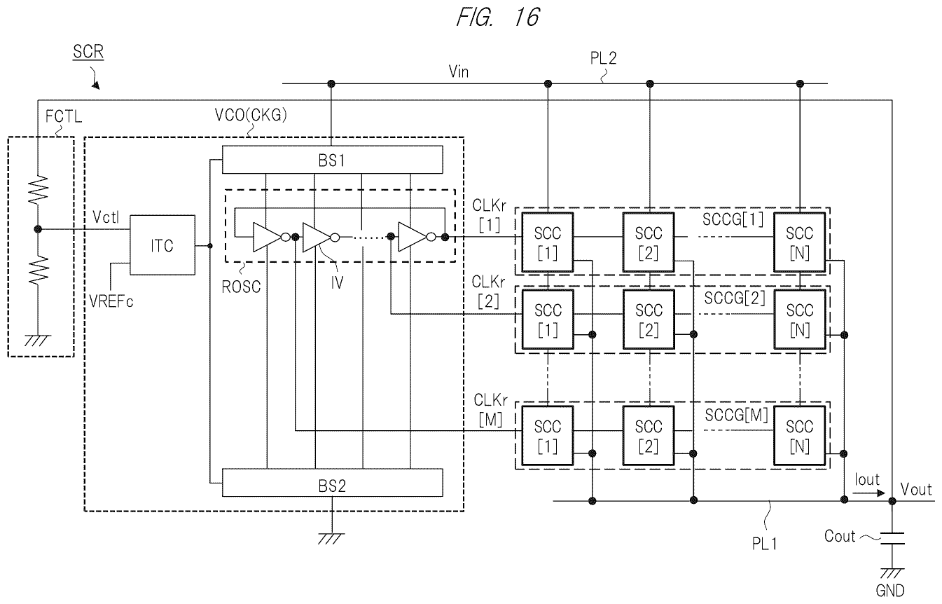

FIG. 16 is a circuit block diagram illustrating a detailed configuration example of a switched-capacitor regulator in a semiconductor device according to a third embodiment. The switched-capacitor regulator SCR illustrated in FIG. 16 differs from the configuration illustrated in FIG. 7A in the following two points.

As a first difference, with M being an integer equal to or greater than 2, M groups of switched-capacitor circuit groups SCCG[1] to SCCG[M] are provided. In this specification, the switched-capacitor circuit groups are collectively referred to as switched-capacitor circuit groups SCCG. Each of the M groups of switched-capacitor circuit groups SCCG includes, similarly to the case of FIG. 7A, a plurality of stages, that is, N stages of switched-capacitor circuits SCC[1] to SCC[N]. However, the number of stages of the switched-capacitor circuits SCC may be different for each of the M groups.

As a second difference, the clock generation circuit CKG generates M-phase reference clock signals CLKr[1] to CLKr[M] having phases different from each other. In this specification, the reference clock signals of the respective phases are collectively referred to as reference clock signals CLKr. Then, the clock generation circuit CKG outputs the M-phase reference clock signals CLKr to the first-stage switched-capacitor circuits SCC[1] included in the M groups of switched-capacitor circuit groups SCCG, respectively.

More specifically, the clock generation circuit CKG is composed of, for example, a voltage-controlled oscillator VCO including a ring oscillator circuit ROSC, similarly to the case of FIGS. 7A and 7B. In this case, the voltage-controlled oscillator VCO generates M-phase reference clock signals CLKr by output signals of respective stages of inverter circuits IV constituting the ring oscillator circuit ROSC.

Here, in the method of the embodiment, as described above, multiphase operation is implemented by cascade connection of the switched-capacitor circuits SCC. Therefore, as illustrated in FIG. 16, by inputting the M-phase reference clock signals CLKr to the M groups of switched-capacitor circuit groups SCCG, further multiphasing can be easily implemented. As a result, as compared with the case of FIG. 7, a capacitance of the flying capacitor Cfly in each switched-capacitor circuit SCC can be further reduced.

Consequently, the ripple voltage Vrpl can be further suppressed. Furthermore, by reducing the capacitance of the flying capacitor Cfly, for example, sizes of the respective switches illustrated in FIG. 6A can be reduced, and sizes of the respective logic gates constituting the switch control circuit SWCT can also be reduced. As a result, power consumption in the respective switches and the switch control circuit SWCT can be reduced, thereby suppressing deterioration of power efficiency in the switched-capacitor regulator SCR.

In addition, in each switched-capacitor circuit group SCCG, the number of stages “N” can also be reduced. In this case, for example, transient response characteristics of the load can be improved in some cases. More specifically, in the N stages of switched-capacitor circuits SCC, even when, for example, the first-stage clock signal CLK[1] is stopped, the N-th-stage clock signal CLK[N] is stopped after a delay time of “N×Td”. Therefore, transient response characteristics of the load may deteriorate. By reducing the number of stages “N”, the delay time of “N×Td” can be reduced, and thus transient response characteristics of the load can be improved in some cases.

### <Main Effects of Third Embodiment>

As described above, by using the method according to the third embodiment, effects similar to the various effects described in the first embodiment can be obtained. Furthermore, further suppression of ripple voltage can be implemented.

As described above, the invention made by the present inventor has been specifically described based on the embodiments; however, the present invention is not limited to the above-described embodiments and various modifications can be made without departing from the spirit thereof. For example, the above-described embodiments have been described in detail to clearly explain the present invention, and are not necessarily limited to having all of the configurations described. Moreover, it is possible to replace parts of the configuration of one embodiment with that of another embodiment, and it is also possible to add the configuration of another embodiment to that of one embodiment. Furthermore, with respect to parts of the configuration in each embodiment, it is possible to add to, delete from, or replace them with other configurations.

What is claimed is:

1. A semiconductor device comprising:
a power supply line that supplies power to a predetermined load;
a plurality of stages of switched-capacitor circuits, each of which includes a switch, a switch control circuit, and a flying capacitor, and in which the respective switch control circuits are connected in cascade; and
a clock generation circuit that generates a clock signal and outputs the clock signal to a first-stage switched-capacitor circuit among the plurality of stages of switched-capacitor circuits,
wherein each of the switch control circuits generates a switching signal for the switch by processing an input clock signal from a preceding stage with logic gates, and outputs, to a subsequent stage, an output clock signal obtained by adding a delay to the input clock signal by the logic gates, and
wherein each of the plurality of stages of switched-capacitor circuits supplies power to the common power supply line by alternately switching between a charging operation and a discharging operation for the flying capacitor by switching of the switch.

2. The semiconductor device according to claim 1,
wherein each of the switch control circuits outputs an inverted signal of the input clock signal as the output clock signal.

3. The semiconductor device according to claim 1,
wherein, when a distance between a switched-capacitor circuit arranged closest to the clock generation circuit and the clock generation circuit is defined as a shortest distance, and a distance between a switched-capacitor circuit arranged farthest from the clock generation circuit and the clock generation circuit is defined as a longest distance, the longest distance is twice or more of the shortest distance.

4. The semiconductor device according to claim 3,
wherein the plurality of stages of switched-capacitor circuits is arranged in a plurality of rows while being folded back at intermediate stages from the first-stage switched-capacitor circuit toward a final-stage switched-capacitor circuit.

5. The semiconductor device according to claim 1, further comprising
M groups of switched-capacitor circuit groups, each of which includes the plurality of stages of switched-capacitor circuits,
wherein the clock generation circuit generates M-phase reference clock signals having phases different from each other, and outputs the M-phase reference clock signals to first-stage switched-capacitor circuits included in the M groups of switched-capacitor circuit groups, respectively.

6. The semiconductor device according to claim 5,
wherein the clock generation circuit is a voltage-controlled oscillator including a ring oscillator circuit, and the clock generation circuit generates the M-phase reference clock signals by output signals of respective ones of a plurality of stages of inverter circuits constituting the ring oscillator circuit.
